(19) United States
(12) Patent Application Publication
(10) Pub. No.: US 2018/0273880 A1
(43) Pub. Date: Sep. 27, 2018

(54) SILICON WAFER CLEANER AND METHOD FOR CLEANING SILICON WAFER

(71) Applicant: Sino-American Silicon Products Inc., Hsinchu (TW)

(72) Inventors: Jian-Yu Lin, Hsinchu (TW); Chun-Ho Chen, Hsinchu (TW); I-Ching Li, Hsinchu (TW); Sung-Lin Hsu, Hsinchu (TW)

(73) Assignee: Sino-American Silicon Products Inc., Hsinchu (TW)

(21) Appl. No.: 15/867,743

(22) Filed: Jan. 11, 2018

(30) Foreign Application Priority Data
Mar. 22, 2017 (TW) 106109528

(51) Int. Cl. C11D 3/20; H01L 21/02; B08B 3/08; C11D 3/10; C11D 3/18; C11D 3/04

(52) U.S. Cl. CPC C11D 3/2086; H01L 21/02052; C11D 3/044; C11D 3/10; C11D 3/188; B08B 3/08

(57) ABSTRACT

A cleaner for silicon wafer and a method for cleaning silicon wafer are provided. The cleaner for silicon wafer is essentially consisted of 1-3 wt % of citric acid, 2.5-5 wt % of sodium bicarbonate, limonene, potassium hydroxide and water. The cleaning efficiency may be improved by using the cleaner for silicon wafer to clean the silicon wafer.

### CROSS-REFERENCE TO RELATED APPLICATION

This application claims the priority benefit of Taiwan application serial no. 106109528, filed on Mar. 22, 2017. The entirety of the above-mentioned patent application is hereby incorporated by reference herein and made a part of specification.

### BACKGROUND

### Field of the Invention

The invention relates a cleaning technique for a silicon wafer and more particularly, to a silicon wafer cleaner and a method for cleaning a silicon wafer.

### Description of Related Art

A silicon wafer is one of the essential materials used for substrates of various technologies, for example, a silicon wafer for a solar cell.

In the manufacturing of the silicon wafer for the solar cell, a silicon ingot is sliced by wire saw. However, after the silicon ingot is sliced by the wire saw, a large amount of slicing products (e.g., a coolant, silicon swarf, metals, etc.) remains on a surface of the silicon wafer, and as a processing time is extended, oxides may be formed to facilitate cluster phenomenon occurring, which causes increased cost of a subsequent cleaning process.

In addition, not only the slicing products, but also oil smudges remaining on the silicon wafer have to be removed, and therefore, an adaptive cleaner is in need for effectively cleaning the silicon wafer.

### SUMMARY

The invention provides a silicon wafer cleaner capable of improving cleaning efficiency for a silicon wafer.

The invention provides a method for cleaning a silicon wafer capable of achieving preferable efficiency of cleaning a silicon wafer at a normal temperature.

A silicon wafer cleaner of the invention which is essentially consisted of 1 wt % to 3 wt % of citric acid, 2.5 wt % to 5 wt % of sodium bicarbonate, limonene, potassium hydroxide and a solvent.

In an embodiment of the invention, a content of limonene is 0.2 wt % to 1 wt %.

In an embodiment of the invention, a content of potassium hydroxide is 0.25 wt % to 0.75 wt %.

In an embodiment of the invention, a pH value of the silicon wafer cleaner is 10 or less.

In an embodiment of the invention, the pH value of the silicon wafer cleaner is 7.0 to 10.0.

In an embodiment of the invention, the solvent is water.

A method for cleaning a silicon wafer of the invention includes soaking a silicon wafer in the aforementioned silicon wafer cleaner at a normal temperature.

In another embodiment of the invention, a time of the soaking is 600 seconds (sec) to 1200 sec.

Based on the above, the silicon wafer cleaner of the invention is consisted of the specific composition and the components with specific ratio ranges and thus, can achieve an effect of effectively cleaning the silicon wafer at the normal temperature.

In order to make the aforementioned and other features and advantages of the invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of cleaning a silicon wafer according to an embodiment of the invention.

### DESCRIPTION OF EMBODIMENTS

Hereinafter, the embodiments of invention will be described in detail. However, the embodiments are only exemplary, but the disclosure of the invention is not limited thereto.

In an embodiment of the invention, a silicon wafer cleaner is essentially consisted of: 1 wt % to 3 wt % of citric acid, 2.5 wt % to 5 wt % of sodium bicarbonate, limonene, potassium hydroxide and a solvent. Citric acid and sodium bicarbonate (which is so-called as “soda”) produce sodium citrate, and the produced sodium citrate is dissociated into a citrate. The citrate may be pseudo-bound with metal or surface electrons of silicon in a way like chelating, thereby effectively removing the slicing products from the silicon wafer. Taking silicon swarf of a micron level or a sub-micron level for example, the silicon originally composed of 3D molecules, due to Si atoms contained therein being captured by the citrates, may result in disintegration of the 3D molecules. Potassium hydroxide in the silicon wafer cleaner may cause a size of the micron-level (or sub-micron level) silicon to be further shrunk for disintegration more easily. A content of potassium hydroxide is, for example, between 0.25 wt % and 0.75 wt %. As citric acid and sodium bicarbonate are used in a specific ratio in the present embodiment, the ratio of the two may be manufactured and adjusted based on an environmental condition (which is defined by PH) on demand, which has relatively high degree of freedom in comparison with a cleaner in which the sodium citrate serves as one of the ingredients. In this way, characteristics of a buffer solution may be reinforced, and a range of environmental pH changes may be controlled, and thereby, a speed of preparing the solution is not influenced by solubility in the present embodiment. In comparison, the sodium citrate, when being dissolved in water, has to be heated to accelerate the dissolution. Limonene contained in the silicon wafer cleaner is capable of removing long carbon chain molecules (i.e., oil smudges), where a content of limonene, is for example, between 0.2 wt % and 1 wt %. In the present embodiment, a pH value of the silicon wafer cleaner is, for example, 10.0 or less, e.g., between 7.0 and 10.0.

In the embodiments of the invention, the solvent contained in the silicon wafer cleaner is, for example, water, where types of the water may further be classified as deionized water and RO water, and the solvent is preferably deionized water in terms of the cleaning effect.

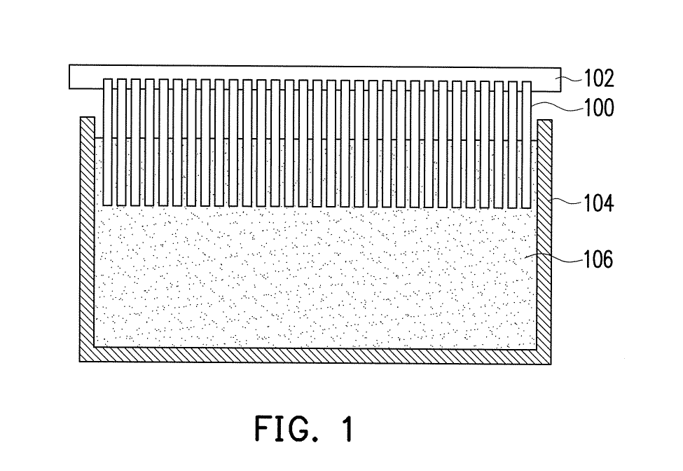

A method for cleaning a silicon wafer of the invention is as illustrated in FIG. 1. A plurality of silicon wafers 100 are fixed by a supporter 102, and the silicon wafers 100 are soaked in a silicon wafer cleaner 106 in a cleaning tank 104 at a normal temperature. The silicon wafer cleaner 106 in this case is the silicon wafer cleaner of the embodiment described above. A time of the soaking may be between 600 seconds (sec) and 1200 sec, but the invention is not limited thereto.

An experiment is provided to verify the effect of the invention, but the invention is not limited to the content set forth below.

### EXPERIMENT EXAMPLE

First, a silicon wafer cleaner consisted of 1 wt % to 3 wt % of citric acid, 2.5 wt % to 5 wt % of sodium bicarbonate, 0.25 wt % to 0.75 wt % of potassium hydroxide, 0.2 wt % to 1 wt % of limonene and water is prepared. Then, a wafer after being processed by using a wire saw is placed in the silicon wafer cleaner at a normal temperature (e.g., 25° C.) for 600 sec.

### Comparative Example

The cleaning of a silicon wafer is performed by using a non-ionic surfactant commonly available in the market as a cleaner in the same conditions of the experiment example.

### Comparison of Cleaning Efficiency

Each of the silicon wafers of the experiment example and the comparative example is sliced into 25 slices, and then, a ratio of an area of the oil smudges in each slice is visually observed. A ratio of the area of the oil smudges to an area of each single slice, if being more than 50%, is counted as 1, while the ratio of the area of the oil smudges to the area of each single slice, if being less than 50%, is counted as 0, and a ratio of an area of remaining oil films is then calculated.

As a result, a ratio of an area with remaining oil films obtained by the experiment example is 50%, namely, a ratio of an area with no remaining oil film in the experiment example is 50%.

A ratio of an area with remaining oil films obtained by the comparative example is 70%, namely, a ratio of an area with no remaining oil film in 30%.

Thus, by comparing the result of the experiment example with the result of the comparative example, the cleaning efficiency is improved by 67% (i.e., 50%/30%=1.67).

In light of the foregoing, the silicon wafer cleaner of the invention is consisted of the specific composition and the components (e.g., citric acid and sodium bicarbonate) with specific ratio ranges and thus, can achieve an effect of effectively cleaning the silicon wafer at the normal temperature.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A silicon wafer cleaner, which is essentially consisted of:
1 wt % to 3 wt % of citric acid;
2.5 wt % to 5 wt % of sodium bicarbonate;
limonene;
potassium hydroxide; and
a solvent.

2. The silicon wafer cleaner according to claim 1, wherein a content of limonene is 0.2 wt % to 1 wt %.

3. The silicon wafer cleaner according to claim 1, wherein a content of potassium hydroxide is 0.25 wt % to 0.75 wt %.

4. The silicon wafer cleaner according to claim 1, wherein a pH value of the silicon wafer cleaner is 10 or less.

5. The silicon wafer cleaner according to claim 4, wherein the pH value of the silicon wafer cleaner is 7.0 to 10.0.

6. The silicon wafer cleaner according to claim 1, wherein the solvent comprises water.

7. A method for cleaning a silicon wafer, comprising:
soaking a silicon wafer in a silicon wafer cleaner at a normal temperature, wherein the silicon wafer cleaner is essentially consisted of:
1 wt % to 3 wt % of citric acid;
2.5 wt % to 5 wt% of sodium bicarbonate;
limonene;
potassium hydroxide; and a solvent.

8. The method for cleaning the silicon wafer according to claim 7, wherein, wherein a time of the soaking is 600 seconds (sec) to 1200 sec.

9. The method for cleaning the silicon wafer according to claim 7, wherein a content of limonene is 0.2 wt % to 1 wt %.

10. The method for cleaning the silicon wafer according to claim 7, wherein a content of potassium hydroxide is 0.25 wt % to 0.75 wt %.

11. The method for cleaning the silicon wafer according to claim 7, wherein a pH value of the silicon wafer cleaner is 10 or less.

12. The method for cleaning the silicon wafer according to claim 11, wherein the pH value of the silicon wafer cleaner is 7.0 to 10.0.

13. The method for cleaning the silicon wafer according to claim 7, wherein the solvent comprises water.
